(19) United States
(12) Patent Application Publication
(10) Pub. No.: US 2025/0166555 A1
(43) Pub. Date: May 22, 2025

(54) BUFFER CIRCUIT, SOURCE DRIVER, AND DISPLAY DEVICE INCLUDING THEREOF

(71) Applicant: SAMSUNG ELECTRONICS CO., LTD., Suwon-si (KR)

(72) Inventors: Minsung KIM, Suwon-si (KR); Seung-Hoon Baek, Suwon-si (KR)

(73) Assignee: SAMSUNG ELECTRONICS CO., LTD., Suwon-si (KR)

(21) Appl. No.: 18/811,287

(22) Filed: Aug. 21, 2024

(30) Foreign Application Priority Data
Nov. 17, 2023 (KR) 10-2023-0159665

(51) Int. Cl. G09G 3/32

(52) U.S. Cl. CPC G09G 3/32; G09G 2300/0828; G09G 2310/0275; G09G 2310/0286; G09G 2310/0289; G09G 2310/0291; G09G 2310/08; G09G 2330/023

(57) ABSTRACT

According to an embodiment, a buffer circuit includes an operational amplifier configured to output an output voltage based on voltages of a first output node and a second output node which vary in response to an input voltage of the operational amplifier, and a slew rate compensating circuit configured to receive the input voltage and the output voltage, generate a compensation current which is proportional to a voltage difference between the input voltage and the output voltage, and supply the compensation current to the first output node or the second output node.

### CROSS-REFERENCE TO RELATED APPLICATION

This application claims priority to and the benefit of Korean Patent Application No. 10-2023-0159665 filed in the Korean Intellectual Property Office on Nov. 17, 2023, the entire contents of which are incorporated herein by reference.

### BACKGROUND

### 1. Field

The present disclosure relates to a buffer circuit, a source driver, and a display device including the same.

### 2. Description of Related Art

Generally, a display device displays images to provide various visual information to a user. A display panel of the display device may include a plurality of pixels, and each of the plurality of pixels emits light with a predetermined luminance to display images. A display driver integrated circuit (DDI) may be used to drive these pixels.

In recent years, there has been a focus on reducing the power consumption of display devices. One method involves driving the DDI at a lower driving voltage. However, this may lead to a slower slew rate in a buffer circuit of the DDI. On the other hand, a higher display frame rate may be required improve the user experience. Therefore, studies have been conducted to find ways to increase a slew rate of the buffer circuit while maintaining low power consumption.

### SUMMARY

One or more embodiments of the present disclosure provide a buffer circuit having a high slew rate, a source driver, and a display device including the same.

The buffer circuit may operate through a small voltage difference between an input voltage and an output voltage.

According to an aspect of the present disclosure, a buffer circuit may include: an operational amplifier configured to output an output voltage based on a voltage of a first output node and a voltage of a second output node which vary in response to an input voltage of the operational amplifier; and a slew rate compensating circuit configured to receive the input voltage and the output voltage, generate a compensation current which is proportional to a voltage difference between the input voltage and the output voltage, and supply the compensation current to the first output node or the second output node.

The slew rate compensation circuit is further configured to provide the compensation current, based on the voltage difference occurring between the input voltage and the output voltage.

The operational amplifier is further configured to drop the output voltage based on the voltage of the first output node and raise the output voltage based on the voltage of the second output node, and based on the input voltage being greater than the output voltage, the slew rate compensating circuit is further configured to supply the compensation current to the first output node to suppress a decrease of the output voltage, and based on the input voltage being less than the output voltage, supply the compensation current to the second output node to suppress an increase of the output voltage.

The compensation current which is supplied to the first output node may include a first compensation current provided to the first output node to suppress the decrease of the output voltage, and wherein the compensation current which is supplied to the second output node may include a second compensation current provided to the second output node to suppress the increase of the output voltage.

The slew rate compensating circuit may include: a current generator configured to receive the input voltage and the output voltage and generate a current proportional to the voltage difference between the input voltage and the output voltage, and a compensation current generator configured to perform an operation of a current mirror and generate the compensation current.

The current generator may include: a first amplifier including a first input stage to which the input voltage is applied, a second input stage connected to a first node, and an output stage configured to output the input voltage, a first resistor which is connected between an output node configured to output the output voltage and the first node, a second amplifier which may include a first input stage to which the input voltage is applied, a second input stage connected to a second node, and an output stage configured to output the input voltage, and a second resistor which is connected between the output node and the second node.

Based on the input voltage being greater than the output voltage, a current proportional to the voltage difference between the input voltage and the output voltage flows in the first resistor, and based on the input voltage being less than the output voltage, a current proportional to the voltage difference between the input voltage and the output voltage flows in the second resistor.

The operational amplifier is further configured to drop the output voltage based on the voltage of the first output node and raise the output voltage based on the voltage of the second output node. The compensation current generator is further configured to perform the operation of the current mirror for the current which flows in the first resistor, supply the compensation current to the first output node, perform the operation of the current mirror for the current which flows in the second resistor, and supply the compensation current to the second output node.

Based on the input voltage being greater than the output voltage, the first amplifier is further configured to be enabled by a first enable signal. Based on the input voltage being less than the output voltage, the second amplifier is further configured to be enabled by a second enable signal.

The current generator may include: an amplifier including a first input stage to which the input voltage is applied, a second input stage connected to a first node, and an output stage configured to output the input voltage, a resistor connected between the first node and an output node configured to output the output voltage, and a plurality of switches configured to supply a current flowing from the first node to the output node to the compensation current generator based on the input voltage being greater than the output voltage, and supply a current flowing from the output node to the first node to the compensation current generator based on the input voltage being less than the output voltage.

Based on the input voltage being different from the output voltage, the amplifier is further configured to be enabled by an enable signal.

The operational amplifier may include: an input stage configured to receive the input voltage and the output voltage and determine a magnitude difference between the input voltage and the output voltage, a load stage configured to generate load currents corresponding to the magnitude difference between the input voltage and the output voltage and supply the load currents from the first output node and the second output node to the input stage, and an output stage configured to generate the output voltage based on voltages of the first output node and the second output node.

The input stage of the operational amplifier may include a first input stage and a second input stage. The buffer circuit may further include an upper bias circuit configured to supply a first bias current to the first input stage, and a lower bias circuit configured to supply a second bias current to the second input stage.

The input stage may include: a first input stage including P-type transistors and configured to receive a pulling load current from the load stage, and a second input stage including N-type transistors and configured to receive a pushing load current from the load stage.

The load stage may include: an upper current mirror circuit electrically connected to the second input stage and configured to supply a current to the load stage, a lower current mirror circuit electrically connected to the first input stage and may supply a current to the load stage, a first connection circuit configured to electrically connect a first output terminal of the upper current mirror circuit and a first output terminal of the lower current mirror circuit, a second connection circuit configured to electrically connect a second output terminal of the upper current mirror circuit and a second output terminal of the lower current mirror circuit, a first capacitor connected between the first output terminal of the upper current mirror circuit and an output terminal of the output stage, and a second capacitor connected between the first output terminal of the lower current mirror circuit and the output terminal of the output stage.

According to another aspect of the present disclosure, a source driver may include: a shift register configured to sample data in response to a horizontal synchronizing signal and output sampled image data, a level shifter configured to shift a voltage level of the image data, a digital-analog converter (DAC) configured to generate an analog signal corresponding to the image data having the shifted voltage level, and an output buffer circuit configured to buffer the analog signal to output the analog signal to source lines as a data signal, and generate a compensation current which is proportional to a voltage difference of the analog signal and the data signal.

The output buffer circuit may include: a plurality of operational amplifiers configured to amplify the analog signal to generate the data signal, and a plurality of slew rate compensating circuits configured to supply the compensation current to the plurality of operational amplifiers.

The slew rate compensating circuit is further configured to supply the compensation current based on the voltage difference occurring between the analog signal and the data signal.

The slew rate compensating circuit may include: a current generator configured to receive the analog signal and the data signal and generate the compensation current proportional to the voltage difference between the analog signal and the data signal, and a compensation current generator configured to perform an operation of a current mirror for the current and generate the compensation current.

According to another aspect of the present disclosure, a display device may include: a pixel array including a plurality of pixels, a timing controller configured to obtain image data from an image signal, and a source driver configured to convert the image data into a data signal and generate a compensation current proportional to a voltage difference between the image signal and the data signal based on the image data.

According to another aspect of the present disclosure, a buffer circuit may include: an operational amplifier comprising an input node configured to receive an input voltage and an output node configured to receive an output voltage; and a slew rate compensating circuit including: a first resistor provided and a second resistor connected in series with a common junction node between the first resistor provided and the second resistor, wherein the first resistor and the second resistor comprise a first opposite end node and a second opposite end node which are provided opposite to the common junction node, respectively; a first mirror circuit connected to the first opposite end node and configured to mirror a rising compensation current flowing through the first resistor based on a difference between the input voltage and the output voltage; and a second mirror circuit connected to the second opposite end node and configured to mirror a falling compensation current flowing through the second resistor based on a difference between the input voltage and the output voltage.

### BRIEF DESCRIPTION OF THE DRAWINGS

FIG. 1 is a circuit diagram of a buffer circuit according to an exemplary embodiment.

FIG. 2 is a block diagram of a buffer circuit according to an exemplary embodiment.

FIG. 3 is a circuit diagram illustrating an input stage and bias circuits included in a buffer circuit according to an exemplary embodiment.

FIG. 4 is a circuit diagram illustrating an example of a load stage and an output stage included in a buffer circuit according to an exemplary embodiment.

FIG. 5 is a circuit diagram illustrating another example of a load stage and an output stage included in a buffer circuit according to an exemplary embodiment.

FIG. 6 is a block diagram illustrating a slew rate compensating circuit of a buffer circuit according to an exemplary embodiment.

FIG. 7 is a circuit diagram of a slew rate compensating circuit of a buffer circuit according to an exemplary embodiment.

FIG. 8 is a graph illustrating a compensation current according to a voltage difference between an input voltage and an output voltage of a buffer circuit according to an exemplary embodiment.

FIG. 9 is a timing diagram illustrating an input voltage and an output voltage of a buffer circuit according to an exemplary embodiment.

FIG. 10 is a circuit diagram of a slew rate compensating circuit of a buffer circuit according to an exemplary embodiment.

FIG. 11 is a timing diagram illustrating an example of an input voltage, an output voltage, and enable signals of a buffer circuit according to an exemplary embodiment.

FIG. 12 is a circuit diagram of a slew rate compensating circuit of a buffer circuit according to an exemplary embodiment.

FIG. 13 is a timing diagram illustrating an example of an input voltage, an output voltage, and a switching control signal of a buffer circuit according to an exemplary embodiment.

FIG. 14 is a circuit diagram of a slew rate compensating circuit of a buffer circuit according to an exemplary embodiment.

FIG. 15 is a timing diagram illustrating an example of an input voltage, an output voltage, and switching control signals of a buffer circuit according to an exemplary embodiment.

FIG. 16 is a block diagram illustrating a source driver including a buffer circuit according to an exemplary embodiment.

FIG. 17 is a block diagram illustrating a display device including a source driver according to an exemplary embodiment.

FIG. 18 is a view for explaining a display system according to an exemplary embodiment.

### DETAILED DESCRIPTION OF THE EMBODIMENTS

In the following detailed description, only certain exemplary embodiments of the present invention have been shown and described, simply by way of illustration. As those skilled in the art would realize, the described embodiments may be modified in various different ways, all without departing from the spirit or scope of the present invention.

Accordingly, the drawings and description are to be regarded as illustrative in nature and not restrictive. Like reference numerals designate like elements throughout the specification. In the flowchart described with reference to the drawing, an operation order may be changed, several operations may be merged or some operation may be divided or a specific operation may not be performed.

Further, expression described as a singular form may be interpreted as singular or plural unless explicit expression such as “one” or “single” is used. Terms including an ordinary number, such as first and second, are used for describing various constituent elements, but the constituent elements are not limited by the terms. The terms are used only to discriminate one constituent element from another constituent element.

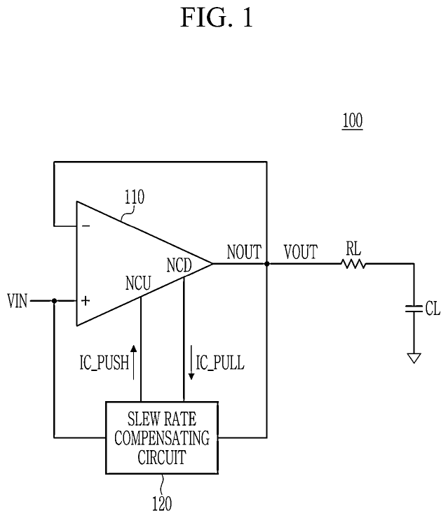

FIG. 1 is a circuit diagram of a buffer circuit according to an exemplary embodiment.

Referring to FIG. 1, a buffer circuit 100 may include an operational amplifier 110 and a slew rate compensating circuit 120. The buffer circuit 100 may buffer an input voltage (VIN) and outputs an output voltage (VOUT). The buffer circuit 100 may be connected to an output node (NOUT) and the output node (NOUT) may be connected to a load resistor RL and a load capacitor CL. As the distance increases from the output node NOUT, transmission of the output voltage VOUT may be delayed by the load resistor RL and the load capacitor CL.

The first input stage (e.g., a non-inverting input stage) (+) of the operational amplifier 110 may receive an input voltage VIN and the output stage of the operational amplifier 110 may be connected to the output node NOUT and outputs the output voltage VOUT. A second input stage (e.g., an inverting input stage) (−) of the operational amplifier 110 may be connected to the output node NOUT. The operational amplifier 110 may amplify the input voltage VIN and outputs the output voltage VOUT to the output stage.

The slew rate compensating circuit 120 may receive the input voltage VIN and the output voltage VOUT. The slew rate compensating circuit 120 may be connected to the first input stage (+) and the output stage of the operational amplifier 110. The slew rate compensating circuit 120 may generate compensation currents IC_PUSH and IC_PULL based on a voltage difference between the input voltage VIN and the output voltage VOUT. The slew rate compensating circuit 120 may output compensation currents IC_PULL and IC_PUSH to a first output node NCD and a second output node NCU of the operational amplifier 110, respectively. The slew rate compensating circuit 120 may reduce a transition time when the output voltage VOUT of the operational amplifier 110 drops by the compensation current IC_PUSH and may reduce a transition time when the output voltage VOUT of the operational amplifier 110 rises by the compensation current IC_PULL.

In some exemplary embodiment, the slew rate compensating circuit 120 may include a resistor and an amplifier, wherein the resistor includes a pair of terminals that are connected between the input voltage VIN and the output voltage VOUT. The input voltage VIN may be supplied to one terminal of the resistor by means of the amplifier. The amplifier may receive the input voltage VIN and may output the input voltage VIN through virtual short-circuit. The slew rate compensating circuit 120 may generate the compensation currents IC_PUSH and IC_PULL based on a current which flows through the resistor.

According to an embodiment, when a voltage difference is generated between the input voltage VIN and the output voltage VOUT, the slew rate compensating circuit 120 may generate the compensation currents IC_PUSH and IC_PULL even with a fine voltage difference so that a slew rate of the buffer circuit 100 which operates at a low driving voltage may be improved.

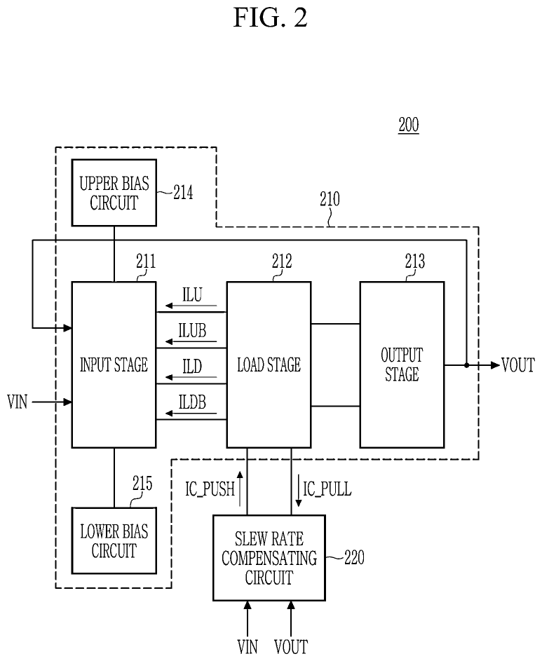

FIG. 2 is a block diagram of a buffer circuit according to an embodiment.

Referring to FIG. 2, the buffer circuit 200 may include an operational amplifier 210 and a slew rate compensating circuit 220. The operational amplifier 210 may have a rail-to-rail structure having a dual input stage structure. In addition, an input stage of the operational amplifier 210 may have a single structure.

The operational amplifier 210 may amplify an input voltage VIN to generate an output voltage VOUT. The slew rate compensating circuit 220 may generate compensation currents IC_PUSH and IC_PULL based on difference of the input voltage VIN and the output voltage VOUT and may supply the compensation currents IC_PUSH and IC_PULL to a load stage (LOAD STAGE) 212 of the operational amplifier 210. Accordingly, the slew rate compensating circuit 220 may reduce a transition time of the output voltage VOUT output from the operational amplifier 210.

Specifically, the operational amplifier 210 may include an input stage 211, a load stage 212, an output stage 213, an upper bias circuit 214, and a lower bias circuit 215.

The input stage 211 may receive the input voltage VIN and may also receive the output voltage VOUT as feedback, and may determine a magnitude difference of the input voltage VIN and the output voltage VOUT.

The load stage 212 may perform a slew rate compensation operation using the first compensation current IC_PULL and the second compensation current IC_PUSH. The load stage 212 may generate load currents ILU, ILUB, ILD, and ILDB corresponding to a voltage difference of the input voltage VIN and the output voltage VOUT and may supply the load currents ILU, ILUB, ILD, and ILDB to the input stage 211. The upper bias circuit 214 and the lower bias circuit 215 may supply bias currents to the input stage 211.

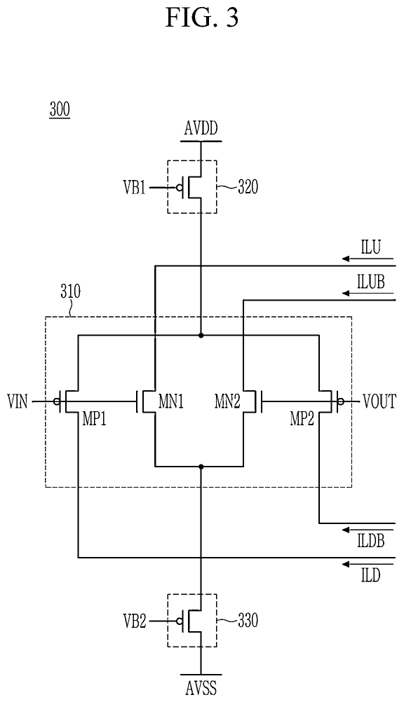

FIG. 3 is a circuit diagram illustrating an input stage and bias circuits included in a buffer circuit according to an embodiment.

Referring to FIGS. 2 and 3, the input stage 310 may include a first input stage which may include P-type transistors MP1 and MP2 and may receive pulling load currents ILD and ILDB from the load stage 212, and a second input stage which may include N-type transistors MN1 and MN2 and may receive pushing load currents ILU and ILUB from the load stage 212.

The upper bias circuit 320 may supply a first bias current to the first input stage based on a bias voltage VB1, and the lower bias circuit 180 may supply a second bias current to the second input stage based on a bias voltage VB2.

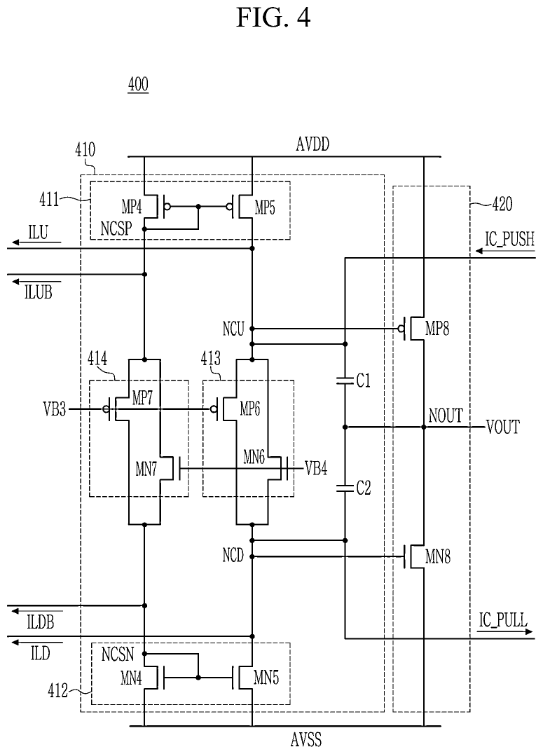

FIG. 4 is a circuit diagram illustrating an example of a load stage and an output stage included in a buffer circuit according to an embodiment.

Referring to FIGS. 2 to 4, the load stage 212 may include an upper current mirror circuit 411, a lower current mirror circuit 412, a first connection circuit 413, a second connection circuit 414, a first capacitor C1, and a second capacitor C2.

The upper current mirror circuit 411 may include P-type transistors MP4 and MP5 which are connected in the form of current mirror, and the lower current mirror circuit 412 may include N-type transistors MN4 and MN5 which are connected in the form of current mirror. The upper current mirror circuit 411 may be electrically connected to the second input stage of FIG. 3 and may supply the pushing load currents ILU and ILUB. The lower current mirror circuit 412 may be electrically connected to the first input stage of FIG. 3 and may supply the pulling load currents ILD and ILDB.

The first connection circuit 413 may include a P-type transistor MP6 which operates in response to a third bias voltage VB3 and a N-type transistor MN6 which operates in response to a fourth bias voltage VB4. The second connection circuit 414 may include a P-type transistor MP7 which operates in response to the third bias voltage VB3 and a N-type transistor MN7 which operates in response to the fourth bias voltage VB4. The first connection circuit 413 may electrically connect the first output node NCU of the upper current mirror circuit 411 and the first output node NCD of the lower current mirror circuit 412. The second connection circuit 414 may electrically connect a second output node NCSP of the upper current mirror circuit 411 and a second output node NCSN of the lower current mirror circuit 412. The first capacitor C1 may be connected between the first output node NCU of the upper current mirror circuit 411 and the output node NOUT of the output stage 420 and the second capacitor C2 may be connected between the first output node NCD of the lower current mirror circuit 412 and the output node NOUT of the output stage 420.

The output stage 420 may include a P-type transistor MP8 which has a gate connected to the first output node NCU of the upper current mirror circuit 411 and is connected between a first power voltage AVDD and the output terminal NOUT, and a N-type transistor MN8 which has a gate connected to the first output node NCD of the lower current mirror circuit 412 and is connected between the output terminal NOUT and the second power voltage AVSS.

The second compensation current IC_PUSH may be supplied to the first output node NCU of the upper current mirror circuit 411, and the first compensation current IC_PULL may be supplied to the first output node NCD of the lower current mirror circuit 412. The pushing load current ILU may flow from the first output node NCU of the upper current mirror circuit 411 to the second input stage which may be configured by N-type transistors MN1 and MN2 included in the input stage 310 and the pushing load current ILUB may flow from the second output node NCSP of the upper current mirror circuit 411 to the second input stage included in the input stage 310. The pulling load current ILD may flow from the first input stage which is configured by the P-type transistors MP1 and MP2 included in the input stage 310 to the first output node NCD of the lower current mirror circuit 412, and the pulling load current ILDB may flow from the first input stage included in the input stage 310 to the second output node NCSN of the lower current mirror circuit 412.

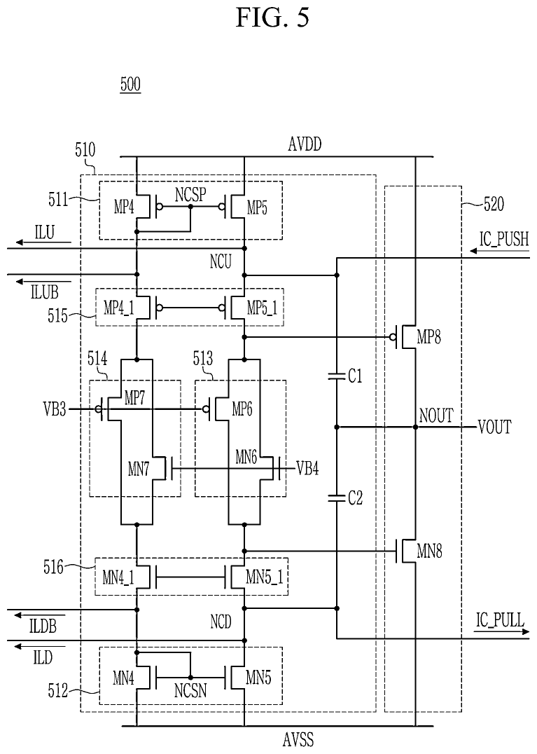

FIG. 5 is a circuit diagram illustrating another example of a load stage and an output stage included in a buffer circuit according to an embodiment.

Referring to FIGS. 2, 3, and 5, the load stage 510 may include an upper cascode circuit 515 including P-type transistors MP4_1 and MP5_1 and a lower cascode circuit 516 including N-type transistors MN4_1 and MN5_1. The upper cascode circuit 515 may be connected between the upper current mirror circuit 511 and the connection circuits 513 and 514 and operates in response to the bias voltage VB5. The lower cascode circuit 516 may be connected between the lower current mirror circuit 512 and the connection circuits 513 and 514 and operates in response to the bias voltage VB6. Except for the upper cascode circuit 515 and the lower cascode circuit 516, the circuit of the load stage 510 illustrated in FIG. 5 may have a similar configuration to the circuit of the load stage 410 illustrated in FIG. 4. Accordingly, the load stage 510 illustrated in FIG. 5 may operate to be similar to the load stage 410 illustrated in FIG. 4. The load stage 510 having the cascode circuits 515 and 516 may have a large output impedance so that the operational amplifier and the buffer circuit which include the load stage 510 acquire a high voltage gain.

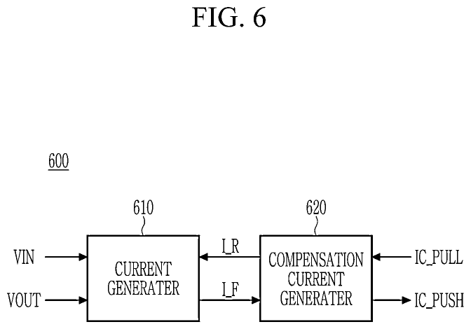

FIG. 6 is a block diagram illustrating a slew rate compensating circuit of a buffer circuit according to an embodiment.

Referring to FIG. 6, a slew rate compensating circuit 600 may include a current generator 610 and a compensation current generator 620.

The current generator 610 may receive the input voltage VIN and the output voltage VOUT and may generate currents I_R and I_F based on the difference of the input voltage VIN and the output voltage VOUT. When the input voltage VIN is greater than the output voltage VOUT, the current generator 610 may generate a current I_R and when the output voltage VOUT is greater than the input voltage VIN, may generate a current I_F. In some embodiment, a magnitude of the current I_R (or the current I_F) when a magnitude difference between the input voltage VIN and the output voltage VOUT is a first value, may be greater than a magnitude of the current I_R (or the current I_F) when a magnitude difference between the input voltage VIN and the output voltage VOUT is a second value which is less than the first value. When the input voltage VIN is greater than the output voltage VOUT, as the magnitude difference between the input voltage VIN and the output voltage VOUT increases, the current I_R may increase. When the output voltage VOUT is greater than the input voltage VIN, as the magnitude difference between the input voltage VIN and the output voltage VOUT increases, the current I_F may increase. For example, the current ID may be proportional to the difference between the input voltage VIN and the output voltage VOUT.

The compensation current generator 620 may receive the current I_R/I_F and may generate a compensation current IC_PULL/IC_PUSH corresponding to the current I_R/I_F. The compensation current generator 620 may perform a current mirror operation of the current I_R and may generate a first compensation current IC_PULL. The compensation current generator 620 may perform a current mirror operation for the current I_F and may generate a second compensation current IC_PUSH.

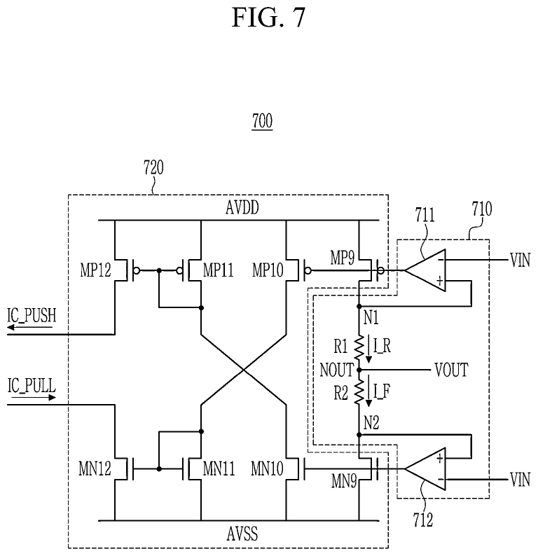

FIG. 7 is a circuit diagram of a slew rate compensating circuit of a buffer circuit according to an embodiment.

Referring to FIG. 7, the slew rate compensating circuit 700 may include a current generator 710 and a compensation current generator 720. The slew rate compensating circuit 700 may generate a first compensation current IC_PULL or a second compensation current IC_PUSH based on a difference of the input voltage VIN and the output voltage VOUT. The first compensation current IC_PULL and the second compensation current IC_PUSH may be also referred to as a falling compensation current and a rising compensation current, respectively.

The current generator 710 may include a first amplifier 711 including a first input stage to which an input voltage VIN is applied, a second input stage connected to the first node N1, and an output stage which outputs an input voltage VIN, a resistor R1 connected between the first node N1 and the output node NOUT, a second amplifier 712 which includes a first input stage to which the input voltage VIN is applied, an a second input stage connected to the second node N2, and an output stage which outputs an input voltage VIN a resistor R2 which is connected between the second node N2 and the output node NOUT. The output node NOUT may correspond to a common junction node provided between the resistor R1 and R2.

The compensation current generator 720 may include transistors MP9, MP10, MN11, and MN12 and transistors MN9, MN10, MP11, and MP12. The transistors MP9, MP10, MP11, and MP12 may constitute a first mirror circuit configured to mirror current I_R flowing through the resistor R1 based on a difference from the input voltage VIN to the output voltage VOUT

$$( e . g . , \frac{VIN - VOUT}{R 1} ) .$$

The transistors MN9, MN10, MN11, and MN12 may constitute a second mirror circuit configured to mirror current I_F flowing through the resistor R2 based on a difference from the output voltage VOUT to the input voltage VIN (e.g., VOUT-VIN)

$$( e . g . , \frac{VOUT - VIN}{R 2} ) .$$

The P-type transistor MP9 may include a source connected to a first power voltage AVDD, a drain connected to the first node N1, and a gate connected to the output stage of the first amplifier 711. The P-type transistor MP10 may include a source connected to the first power voltage AVDD, a drain connected to a drain of the N-type transistor MN11, and a gate connected to the output stage of the first amplifier 711. The N-type transistor MN11 may include a source connected to a second power voltage AVSS, and a drain and a gate which are commonly connected to the drain of the P-type transistor MP10. The N-type transistor MN12 may include a gate connected to the gate of the N-type transistor MN12, a source connected to a second power voltage AVSS, and a drain through which the first compensation current IC_PULL is output.

The N-type transistor MN9 may include a source connected to the second power voltage AVSS, a drain connected to the second node N2, and a gate connected to the output stage of the second amplifier 712. The N-type transistor MN10 may include a source connected to the second power voltage AVSS, a drain connected to the drain of the P-type transistor MP11, and a gate connected to the output stage of the second amplifier 712. The P-type transistor MP11 may include a source connected to a first power voltage AVDD, and a drain and a gate which are commonly connected to the drain of the N-type transistor MN10. The P-type transistor MP12 may include a gate connected to the gate of the P-type transistor MP12, a source connected to the first power voltage AVDD, and a drain through which the second compensation current IC_PUSH may be output.

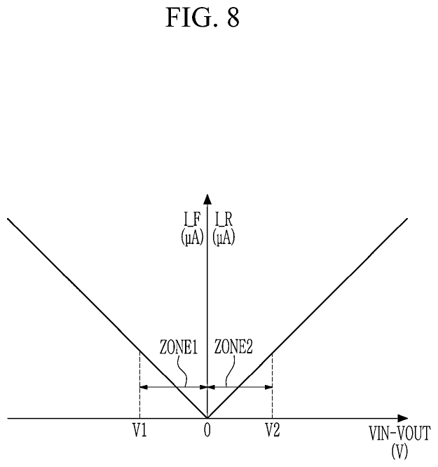

FIG. 8 is a graph illustrating a compensation current according to a voltage difference between an input voltage and an output voltage of a buffer circuit according to an embodiment.

Referring to FIGS. 7 and 8, when there is a voltage difference between the input voltage VIN and the output voltage VOUT, currents I_R and I_F may be generated. Magnitudes of the currents I_R and I_F may vary based on the difference of the input voltage VIN and the output voltage VOUT. The currents I_R and I_F may be calculated based on the following Equations 1 and 2.

$$I\_R = \frac{( VIN - VOUT )}{R 1} \qquad ( Equation 1 )$$

$$I\_F = \frac{( VOUT - VIN )}{R 2} \qquad ( Equation 2 )$$

When the input voltage VIN is greater than the output voltage VOUT, the greater the magnitude difference between the input voltage VIN and the output voltage VOUT, the greater the current I_R may be output. When the output voltage VOUT is greater than the input voltage VIN, the greater the magnitude difference between the input voltage VIN and the output voltage VOUT, the greater the current I_F may be output. For example, the magnitudes of the currents I_R and I_F are proportional to the magnitude difference of the input voltage VIN and the output voltage VOUT. Even in a region ZONE1 in which the magnitude difference of the input voltage VIN and the output voltage VOUT is the first voltage V1 to 0, the current I_F may be generated. Even in a region ZONE2 in which the magnitude difference of the input voltage VIN and the output voltage VOUT is in a range from 0 to the second voltage V2, the current I_R may be generated. That is, the currents I_R and I_F are generated by a small voltage difference between the input voltage VIN and the output voltage VOUT.

Hereinafter, an operation of a buffer circuit according to an embodiment will be described with reference to FIGS. 1 to 8.

The buffer circuit may increase a slew rate of the output voltage VOUT of the buffer circuit using the slew rate compensating circuits 600 and 700 of FIGS. 6 and 7.

When a magnitude of the input voltage VIN is greater than a magnitude of the output voltage VOUT, a magnitude of the pulling load current ILD of the first input stage configured by the P-type transistors MP1 and MP2 included in the input stage 310 may be reduced and the pulling load current ILDB may be increased. Further, the magnitude of the pushing load current ILU of the second input stage configured by the N-type transistors MN1 and MN2 included in the input stage 310 may be increased and the pushing load current ILUB may be reduced. At this time, the voltage of the first output node NCU of the upper current mirror circuit 411 of the load stage 400 may be reduced and the voltage of the second output node NCSP may be increased. Further, the voltage of the first output node NCD of the lower current mirror circuit 412 of the load stage 400 may be reduced and the voltage of the second output node NCSN may be increased.

When a magnitude of the input voltage VIN is greater than a magnitude of the output voltage VOUT, a current I_R according to the voltage difference VIN-VOUT at both terminals may flow through a resistor R1 included in the current generator 710 of FIG. 7. Accordingly, the first compensation current IC_PULL may be supplied to the first output node NCD of the lower current mirror circuit 412 or 512 of the load stage 410 or 510 through the current mirrors MP9, MP10, MN11, and MN12. The first compensation current IC_PULL may flow from the first output node NCD of the load stage 410 or 510 to the transistor MN12. That is, the compensation current generator 720 pulls the first compensation current IC_PULL. At this time, the voltage of the first output node NCD of the load stage 410 or 510 may be further lowered by the first compensation current IC_PULL. Accordingly, the N-type transistor MN8 of the output stage 420 or 520 may be quickly turned off by the first compensation current IC_PULL and the dropping of the output voltage VOUT by the N-type transistor MN8 may be suppressed so that the rising time of the output voltage VOUT may be shortened. When the magnitude of the input voltage VIN is greater than the magnitude of the output voltage VOUT, the N-type transistor MN9 included in the current generator 710 forms the diode-connection so that the current I-F according to a voltage difference at both terminals of the resistor R2 is not mirrored as the second compensation current IC_PUSH. That is, the second compensation current IC_PUSH is not supplied to the load stage 410 or 510.

When the magnitude of the input voltage VIN is less than the magnitude of the output voltage VOUT, the pulling load current ILD of the first input stage configured by the P-type transistors MP1 and MP2 included in the input stage 310 may be increased and the pulling load current ILDB may be reduced. A magnitude of the pushing load current ILU of the second input stage configured by the N-type transistors MN1 and MN2 included in the input stage 310 may be reduced and the pushing load current ILUB may be increased. At this time, the voltage of the first output node NCU of the upper current mirror circuit 411 or 511 of the load stage 410 or 510 may be increased and a voltage of the second output node NCSP may be reduced. Further, a voltage of the first output node NCD of the lower current mirror circuit 412 or 512 of the load stage 410 or 510 may be increased and the voltage of the second output node NCSN may be reduced. That is, when the magnitude of the output voltage VOUT is greater than a magnitude of the input voltage VIN, a voltage of the first output node NCU of the upper current mirror circuit 411 or 511 of the load stage 410 or 510 and a voltage of the first output node NCD of the lower current mirror circuit 412 or 512 of the load stage 410 or 510 may be increased.

When the magnitude of the input voltage VIN is less than the magnitude of the output voltage VOUT, a current I_F according to a voltage difference VOUT-VIN at both terminals may flow to the resistor R2 included in the current generator 710 of FIG. 7. Accordingly, the second compensation current IC_PUSH may be supplied to the first output node NCU of the upper current mirror circuit 411 or 511 of the load stage 410 or 510 through the current mirrors MN9, MN10, MP11, and MP12. The second compensation current IC_PUSH may flow from the transistor MP12 to the first output node NCU of the load stage 410 or 510. That is, the compensation current generator 720 pushes the second compensation current IC_PUSH. Accordingly, the voltage of the first output node NCU of the load stage 410 or 510 may be further increased by the second compensation current IC_PUSH. Accordingly, the P-type transistor MP8 of the output stage 420 or 520 is quickly turned off by the second compensation current IC_PUSH and the rising of the output voltage VOUT by the P-type transistor MP8 is suppressed so that the falling time of the output voltage VOUT may be shortened. When the magnitude of the input voltage VIN is less than the magnitude of the output voltage VOUT, the P-type transistor MP9 included in the current generator 710 forms diode-connection so that the current I-R according to a voltage difference at both terminals of the resistor R1 may be not mirrored as the first compensation current IC_PULL. That is, the pushing compensation current IC_PULL may be not supplied to the load stage 410 or 510.

As described above, when the output voltage transitions, the slew rate compensating circuit 700 may generate compensation currents IC_PULL and IC_PUSH based on the magnitude difference of the input voltage VIN and the output voltage VOUT so that the buffer circuit according to the embodiments shortens a transition time of the output voltage VOUT to improve the slew rate.

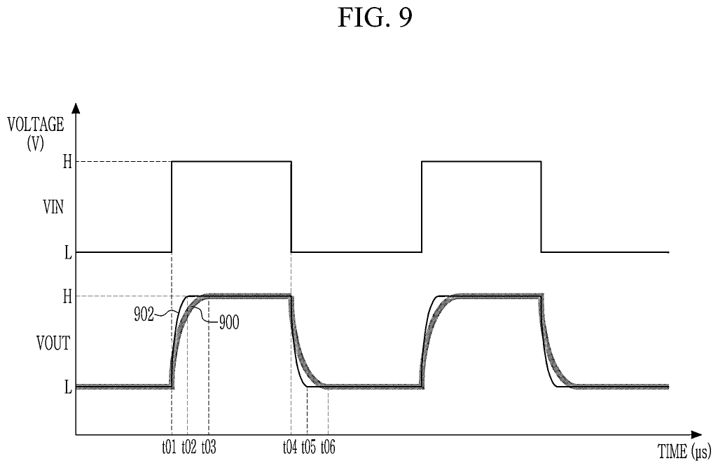

FIG. 9 is a timing diagram illustrating an input voltage and an output voltage of a buffer circuit according to an embodiment.

Referring to FIG. 9, waveforms of the output voltage VOUT according to the input voltage VIN of the buffer circuit according to an embodiment are illustrated. When the input voltage VIN transitions from a low level L to a high level H, a transition time t01 to t02 of the output voltage 902 when the slew rate is compensated using the buffer circuit according to the embodiment may be shorter than a transition time t01 to t03 of the output voltage 900 when the slew rate is not compensated. Further, when the input voltage VIN transitions from a high level H to a low level L, a transition time t04 to t05 of the output voltage 902 when the slew rate is compensated using the buffer circuit according to the embodiment may be shorter than a transition time t04 to t05 of the output voltage 900 when the slew rate is not compensated.

That is, the slew rate of the output voltage 902 when the slew rate is compensated using the buffer circuit according to the embodiment may be improved more than that of the output voltage when the slew rate is not compensated using the buffer circuit according to the embodiment.

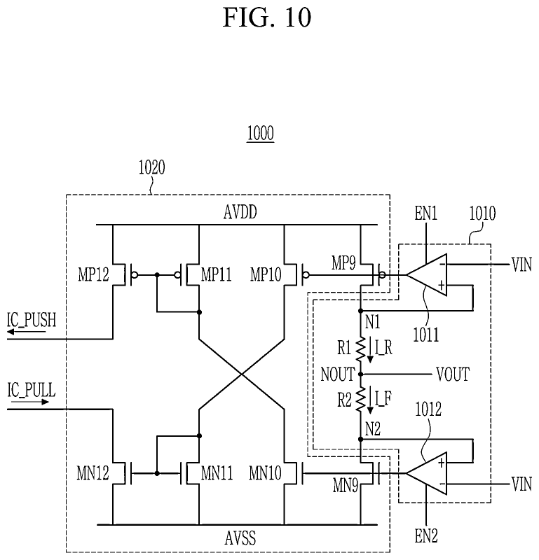

FIG. 10 is a circuit diagram of a slew rate compensating circuit of a buffer circuit according to an embodiment.

Referring to FIG. 10, the slew rate compensating circuit 1000 may include a current generator 1010 and a compensation current generator 1020. The slew rate compensating circuit 1000 may generate a first compensation current IC_PULL or a second compensation current IC_PUSH based on a difference between the input voltage VIN and the output voltage VOUT. Description of components of the slew rate compensating circuit 1000 of FIG. 10 which are the same as or similar to the component of the slew rate compensating circuit 700 of FIG. 7 will be omitted.

The current generator 1010 may include a first amplifier 1011 which includes a first input stage to which an input voltage VIN is applied, a second input stage connected to the first node N1, and an output stage which output the input voltage VIN and is enabled by an enable signal EN1, a resistor R1 connected between the first node N1 and the output node NOUT, a second amplifier 1012 which includes a first input stage to which an input voltage VIN is applied, a second input stage connected to the second node N2, and an output stage which outputs the input voltage VIN and is enabled by an enable signal EN2, and a resistor R2 connected between the second node N2 and the output node NOUT.

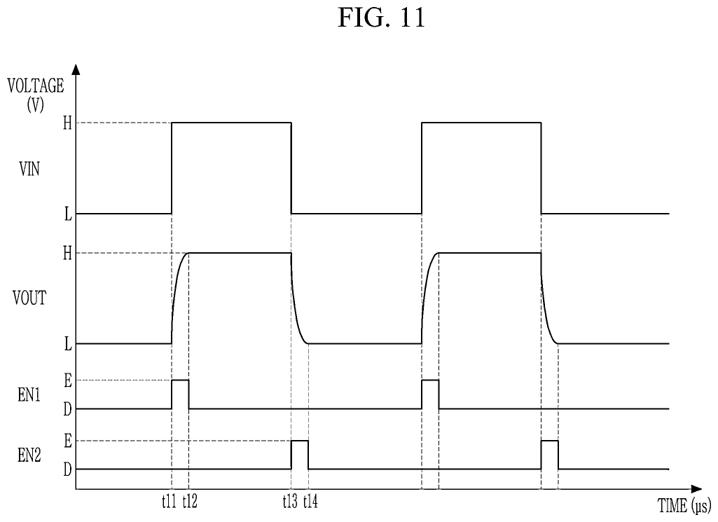

FIG. 11 is a timing diagram illustrating an example of an input voltage, an output voltage, and enable signals of a buffer circuit according to an embodiment.

Referring to FIGS. 10 and 11, at a timing t11, the input voltage VIN transitions from the low level L to the high level H, and during a period of t11 to t12, the magnitude of the input voltage VIN may be greater than the magnitude of the output voltage VOUT. During the period of t11 to t12, the enable signal EN1 may have an enable level E and the enable signal EN2 may have a disable level D. By doing this, the first amplifier 1011 may be enabled and the second amplifier 1012 may be disabled. When first amplifier 1011 is enabled, a current I_R according to a voltage difference VIN-VOUT of both terminals may flow in the resistor R1 included in the current generator 1010. Accordingly, the first compensation current IC_PULL may be supplied to the first output node NCD of the lower current mirror circuit 412 or 512 of the load stage 410 or 510 through the current mirrors MP9, MP10, MN11, and MN12. The first compensation current IC_PULL may flow from the first output node NCD of the load stage 410 or 510 to the transistor MN12. That is, the compensation current generator 1020 pulls the first compensation current IC_PULL. At this time, the voltage of the first output node NCD of the load stage 410 or 510 may be further lowered by the first compensation current IC_PULL. Accordingly, the N-type transistor MN8 of the output stage 420 or 520 may be quickly turned off by first compensation current IC_PULL and the rising time of the output voltage VOUT may be shortened. At this time, the second amplifier 1012 is disabled so that the input voltage VIN is not applied to the second node N2. Accordingly, the current I_F according to a voltage difference of both terminals of the resistor R2 is not generated so that the second compensation current IC_PUSH is not supplied to the load stage 410 or 510.

At a timing t13, the input voltage VIN transitions from the high level H to the low level L, and during a period of t13 to t14, the magnitude of the input voltage VIN may be less than the magnitude of the output voltage VOUT. During the period of t13 to t14, the enable signal EN1 may have a disable level D and the enable signal EN2 may have an enable level E. By doing this, the first amplifier 1011 may be disabled and the second amplifier 1012 may be enabled. When second amplifier 1012 may be enabled, a current I_F according to a voltage difference VOUT-VIN of both terminals may flow in the resistor R2 included in the current generator 1010. Accordingly, the second compensation current IC_PUSH may be supplied to the first output node NCU of the upper current mirror circuit 411 or 511 of the load stage 410 or 510 through the current mirrors MP9, MP10, MN11, and MN12. The second compensation current IC_PUSH may flow from the transistor MP12 to the first output node NCU of the load stage 410 or 510. That is, the compensation current generator 1020 may push the second compensation current IC_PUSH. Therefore, the voltage of the first output node NCU of the load stage 410 or 510 may be further increased by the second compensation current IC_PUSH. Accordingly, the P-type transistor MP8 of the output stage 420 or 520 may be quickly turned off by the second compensation current IC_PUSH and a falling time of the output voltage VOUT may be shortened. At this time, the first amplifier 1011 is disabled so that the input voltage VIN is not applied to the first node N1. Accordingly, the current I_R according to a voltage difference of both terminals of the resistor R1 is not generated so that the first compensation current IC_PULL is not supplied to the load stage 410 or 510.

As described above, in the buffer circuit according to the embodiments, when the output voltage transitions, the slew rate compensating circuit 1000 may generate compensation currents IC_PULL and IC_PUSH based on a magnitude difference between the input voltage VIN and the output voltage VOUT so that the transition time of the output voltage VOUT shortens to improve the slew rate. Further, the first amplifier 1011 and the second amplifier 1012 of the slew rate compensating circuit 1000 selectively operate so that the power consumption may be reduced.

Even though it has been described above than the first amplifier 1011 and the second amplifier 1012 are enabled by different enable signals EN1 and EN2, the first amplifier 1011 and the second amplifier 1012 may receive the same enable signal. In this case, the enable signal will have an enable level E for t11 to t12, t13 to t14. The first amplifier 1011 and the second amplifier 1012 of the slew rate compensating circuit 1000 are enabled for a predetermined period t11 to t12, t13 to t14 so that power consumption may be reduced.

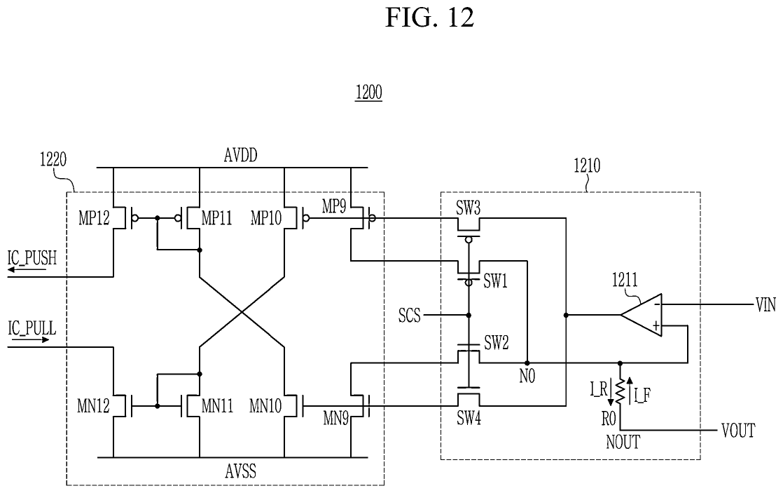

FIG. 12 is a circuit diagram of a slew rate compensating circuit of a buffer circuit according to an embodiment.

Referring to FIG. 12, the slew rate compensating circuit 1200 may include a current generator 1210 and a compensation current generator 1220. The slew rate compensating circuit 1200 may generate a first compensation current IC_PULL or a second compensation current IC_PUSH based on a difference between the input voltage VIN and the output voltage VOUT. Description of components of the slew rate compensating circuit 1200 of FIG. 12 which are the same as or similar to the component of the slew rate compensating circuit 700 of FIG. 7 will be omitted.

The current generator 1210 may include an amplifier 1211 which includes a first input stage to which an input voltage VIN is applied, a second input stage connected to a node NO, and an output stage which outputs the input voltage VIN, a resistor RO connected between the node NO and the output node NOUT, and a plurality of switches SW1, SW2, SW3, and SW4 which connects the current generator 1210 and the compensation current generator 1220.

When the input voltage VIN is greater than the output voltage VOUT, the plurality of switches SW1, SW2, SW3, and SW4 may supply the current I_R flowing from the node NO to the output node NOUT to the compensation current generator 1220 and when the input voltage VIN is lower than the output voltage VOUT, may supply the current I_F flowing from the output node NOUT to the node NO to the compensation current generator 1220.

The first switch SW1 may be connected between the node NO and the drain of the P-type transistor MP9 and may include a gate which receives the switching control signal SCS. Even though the first switch SW1 is illustrated as a P-type transistor, it is not limited thereto.

The second switch SW2 may be connected between the node NO and the drain of the N-type transistor MN9 and may include a gate which receives the switching control signal SCS. Even though the second switch SW2 is illustrated as a N-type transistor, it is not limited thereto.

The third switch SW3 may be connected between the output stage of the amplifier 1211 and the gate of the P-type transistor MP9 and may include a gate which receives the switching control signal SCS. Even though the third switch SW3 is illustrated as a P-type transistor, it is not limited thereto.

The fourth switch SW4 may be connected between the output stage of the amplifier 1211 and the gate of the N-type transistor MN9 and may include a gate which receives the switching control signal SCS. Even though the fourth switch SW4 is illustrated as an N-type transistor, it is not limited thereto.

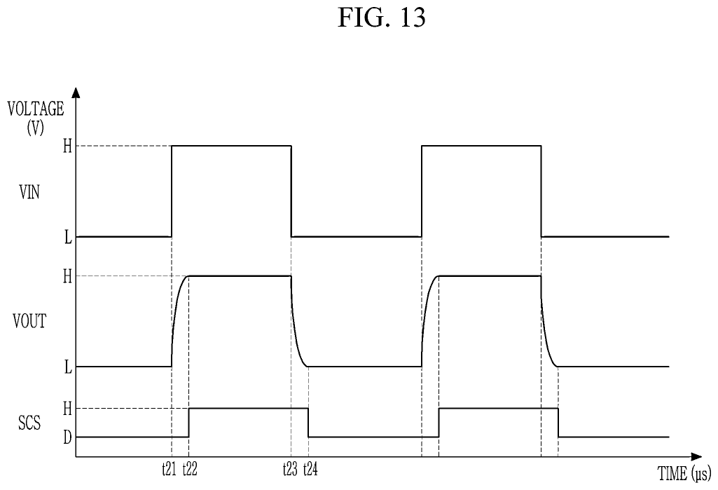

FIG. 13 is a timing diagram illustrating an example of an input voltage, an output voltage, and a switching control signal of a buffer circuit according to an embodiment.

Referring to FIGS. 12 and 13, at a timing t21, the input voltage VIN transitions from the low level L to the high level H, and during a period of t21 to t22, the magnitude of the input voltage VIN may be greater than the magnitude of the output voltage VOUT. A current I_R according to a voltage difference VIN-VOUT of both terminals may flow in the resistor RO included in the current generator 1210. During the period of t21 to t22, the switching control signal SCS may have a low level L. By doing this, the first and third switches SW1 and SW3 are turned on and the second and fourth switches SW2 and SW4 are turned off. The drain of the P-type transistor MP9 may be connected to the node NO and the gate of the P-type transistor MP9 may be connected to the output stage of the amplifier 1211. The current I_R may be supplied to the first output node NCD of the lower current mirror circuit 412 or 512 of the load stage 410 or 510 through the current mirrors MP9, MP10, MN11, and MN12 as a first compensation current IC_PULL. Therefore, the N-type transistor MN8 of the output stage 420 or 520 may be quickly turned off by first compensation current IC_PULL and the rising time of the output voltage VOUT may be shortened. At this time, the second and fourth switches SW2 and SW4 are turned off so that the N-type transistor MN9 is not connected to the node NO and the output stage of the amplifier 1211. Accordingly, the second compensation current IC_PUSH is not supplied to the load stage 410 or 510.

At the timing t23, the input voltage VIN transitions from the high level H to the low level L, and during a period of t23 to t24, the magnitude of the input voltage VIN may be less than the magnitude of the output voltage VOUT. A current I_F according to a voltage difference VOUT-VIN of both terminals may flow in the resistor RO included in the current generator 1210. During the period of t23 to t24, the switching control signal SCS may have a high level H. By doing this, the first and third switches SW1 and SW3 are turned off and the second and fourth switches SW2 and SW4 are turned on. The drain of the N-type transistor MN9 may be connected to the node NO and the gate of the N-type transistor MN9 may be connected to the output stage of the amplifier 1211. The current I_F may be supplied to the first output node NCU of the upper current mirror circuit 412 or 512 of the load stage 410 or 510 through the current mirrors MP9, MP10, MN11, and MN12 as a second compensation current IC_PUSH. Therefore, the P-type transistor MP8 of the output stage 420 or 520 may be quickly turned off by first compensation current IC_PUSH and the falling time of the output voltage VOUT may be shortened. At this time, the first and third switches SW1 and SW3 are turned off so that the P-type transistor MP9 is not connected to the node NO and the output stage of the amplifier 1211. Accordingly, the first compensation current IC_PULL is not supplied to the load stage 410 or 510.

As described above, in the buffer circuit according to the embodiments, when the output voltage transitions, the slew rate compensating circuit 1200 may generate compensation currents IC_PULL and IC_PUSH based on a magnitude difference between the input voltage VIN and the output voltage VOUT so that the transition time of the output voltage VOUT may be shortened to improve the slew rate. Further, the slew rate compensating circuit 1200 may include one amplifier so that an area overhead may be reduced and the power consumption may be reduced.

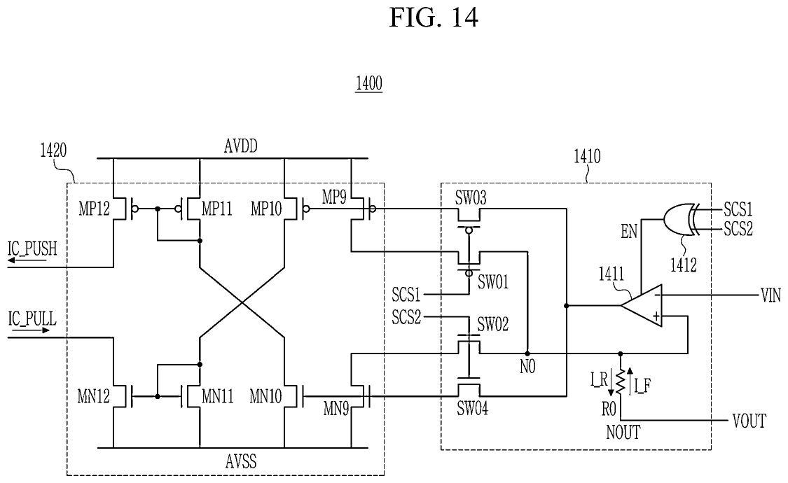

FIG. 14 is a circuit diagram of a slew rate compensating circuit of a buffer circuit according to an embodiment.

Referring to FIG. 14, a slew rate compensating circuit 1400 may include a current generator 1410 and a compensation current generator 1420. The slew rate compensating circuit 1400 may generate a first compensation current IC_PULL or a second compensation current IC_PUSH based on a difference between the input voltage VIN and the output voltage VOUT. Description of components of the slew rate compensating circuit 1400 of FIG. 14 which are the same as or similar to the component of the slew rate compensating circuit 1200 of FIG. 12 will be omitted.

The current generator 1410 may include an exclusive OR (XOR) gate circuit 1412 which receives a first switching control signal SCS1 and a second switching control signal SCS2 and outputs an enable signal EN, an amplifier 1411 which includes a first input stage to which an input voltage VIN is applied, a second input stage connected to a first node N1, and an output stage which outputs the input voltage VIN and is enabled by the enable signal EN, a resistor RO connected between the first node N1 and the output node NOUT, and a plurality of switches SW1, SW2, SW3, and SW4.

The first switch SW1 may be connected between the node NO and the drain of the P-type transistor MP9 and may include a gate which receives a first switching control signal SCS1. Even though the first switch SW1 is illustrated as an N-type transistor, it is not limited thereto.

The second switch SW2 may be connected between the node NO and the drain of the N-type transistor MN9 and may include a gate which receives a second switching control signal SCS2. Even though the second switch SW2 is illustrated as an N-type transistor, it is not limited thereto.

The third switch SW3 may be connected between the output stage of the amplifier 1411 and the gate of the P-type transistor MP9 and may include a gate which receives the first switching control signal SCS1. Even though the third switch SW3 is illustrated as an N-type transistor, it is not limited thereto.

The fourth switch SW4 may be connected between the output stage of the amplifier 1411 and the gate of the N-type transistor MN9 and may include a gate which receives the second switching control signal SCS2. Even though the fourth switch SW4 is illustrated as an N-type transistor, it is not limited thereto.

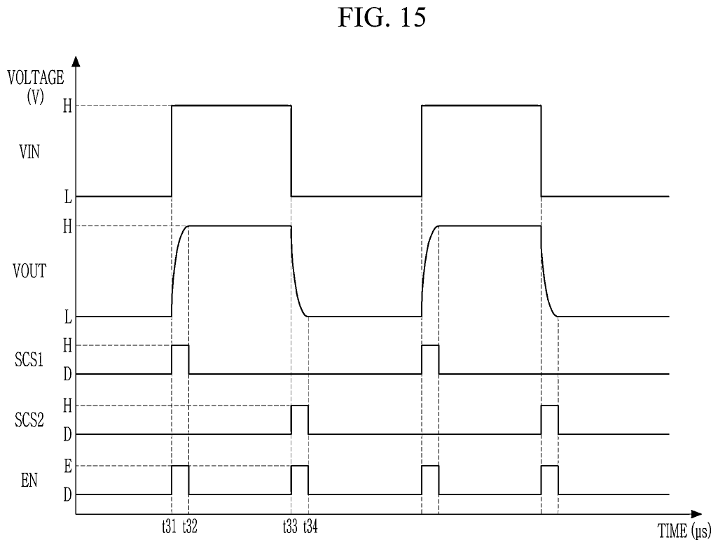

FIG. 15 is a timing diagram illustrating an example of an input voltage, an output voltage, and switching control signals of a buffer circuit according to an embodiment.

Referring to FIGS. 14 and 15, at a timing t31, the input voltage VIN transitions from the low level L to the high level H, and during a period of t31 to t32, the magnitude of the input voltage VIN may be greater than the magnitude of the output voltage VOUT. A current I_R according to a voltage difference VIN-VOUT of both terminals may flow in the resistor RO included in the current generator 1410. During the period of t31 to t32, the first switching control signal SCS1 may have a high level H and the second switching control signal SCS2 may have a low level L. By doing this, the XOR gate circuit 1412 may supply an enable signal EN of an enable level E to the amplifier 1411. The first and third switches SW1 and SW3 are turned on and the second and fourth switches SW2 and SW4 are turned off. The drain of the P-type transistor MP9 may be connected to the node NO and the gate of the P-type transistor MP9 may be connected to the output stage of the amplifier 1411. The current I_R may be supplied to the first output node NCD of the lower current mirror circuit 412 or 512 of the load stage 410 or 510 through the current mirrors MP9, MP10, MN11, and MN12 as a first compensation current IC_PULL. Therefore, the N-type transistor MN8 of the output stage 420 or 520 may be quickly turned off by the first compensation current IC_PULL and the rising time of the output voltage VOUT may be shortened. At this time, the second and fourth switches SW2 and SW4 are turned off so that the N-type transistor MN9 may be not connected to the node NO and the output stage of the amplifier 1411. Accordingly, the second compensation current IC_PUSH may be not supplied to the load stage 410 or 510.

At the timing t33, the input voltage VIN transitions from the high level H to the low level L, and during a period of t33 to t34, the magnitude of the input voltage VIN may be less than the magnitude of the output voltage VOUT. A current I_F according to a voltage difference VOUT-VIN of both terminals may flow in the resistor RO included in the current generator 1410. During the period of t33 to t34, the first switching control signal SCS1 may have a low level L and the second switching control signal SCS2 may have a high level H. By doing this, the XOR gate circuit 1412 may supply an enable signal EN of an enable level E to the amplifier 1411. The first and third switches SW1 and SW3 are turned off and the second and fourth switches SW2 and SW4 are turned on. The drain of the N-type transistor MN9 may be connected to the node NO and the gate of the N-type transistor MN9 may be connected to the output stage of the amplifier 1411. The current I_F may be supplied to the first output node NCU of the upper current mirror circuit 412 or 512 of the load stage 410 or 510 through the current mirrors MN9, MN10, MP11, and MP12 as a second compensation current IC_PUSH. Therefore, the P-type transistor MP8 of the output stage 420 or 520 may be quickly turned off by the first compensation current IC_PUSH and the falling time of the output voltage VOUT may be shortened. At this time, the first and third switches SW1 and SW3 are turned off so that the P-type transistor MP9 may be not connected to the node NO and the output stage of the amplifier 1411. Accordingly, the first compensation current IC_PULL is not supplied to the load stage 410 or 510.

As described above, in the buffer circuit according to the embodiments, when the output voltage transitions, the slew rate compensating circuit 1400 may generate compensation currents IC_PULL and IC_PUSH based on a magnitude difference between the input voltage VIN and the output voltage VOUT so that the transition time of the output voltage VOUT may be shortened to improve the slew rate. Further, the slew rate compensating circuit 1400 may include one amplifier so that an area overhead may be reduced and the power consumption may be reduced.

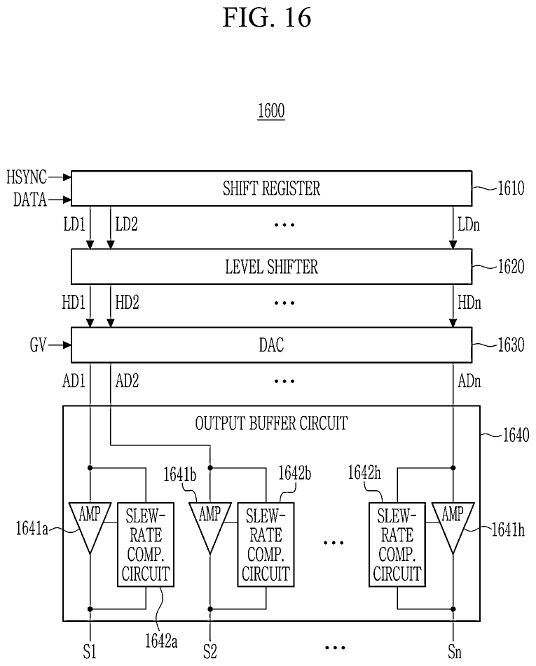

FIG. 16 is a block diagram illustrating a source driver including a buffer circuit according to an embodiment.

Referring to FIG. 16, a source driver 1600 may include a shift register 1610, a level shifter 1620, a digital-analog converter (DAC) 1630, and an output buffer circuit 1640.

The shift register 1610 samples data DATA in response to a horizontal synchronizing signal HSYNC and sampled image data LD1, . . . , LDk provide to the level shifter 1620. The data DATA may include a plurality of source data corresponding to a plurality of source lines and each of the plurality of source data may include a plurality of bits. The shift register 1610 may sample each of the plurality of bits of the data DATA and may generate image data LD1, . . . , LDk having the plurality of bits. The horizontal synchronizing signal HSYNC may be a signal having a predetermined period, and may be a signal which determines a scan period of pixels connected to each of the gate lines.

The level shifter 1620 may shift a level of image data LD1, LD2, . . . , LDn. The level shifter 1620 may receive image data LD1, LD2, . . . , LDn of a low voltage level to output decoded image data HD1, HD2, . . . , HDn of a high voltage level to the DAC 1630. In some embodiment, the image data LD1 may include a plurality of bits and the level shifter 1620 shifts levels of the plurality of bits of the image data LD1, LD2, . . . , LDn to generate decoded image data HD1, HD2, . . . , HDn having a plurality of bits. The level shifter 1620 may receive the digital signals LD1, LD2, . . . , LDn to provide decoded image data HD1, HD2, . . . , HDn whose level transitions to swing between target voltage levels to the DAC 1630.

The DAC 1630 may output analog signals AD1, AD2, . . . , ADn corresponding to the decoded image data HD1, HD2, . . . , HDn. The DAC 1630 may receive a plurality of gamma voltages GV together with the decoded image data HD1, HD2, . . . , HDn. The DAC 1630 may select at least some of the plurality of gamma voltages GV based on the decoded image data HD1, HD2, . . . , HDn to transmit the selected gamma voltages to the output buffer circuit 1640 through an output port as an input voltage.

The output buffer circuit 1640 may buffer the analog signals AD1, AD2, . . . , ADn which are transmitted from the DAC 1630 to output the buffered analog signals to pixels connected to the source lines as data signals S1, S2, . . . , Sn. The output buffer circuit 1640 may include a plurality of operational amplifiers 1641a, 1641b, . . . , 1641h connected to the plurality of source lines and a plurality of slew rate compensating circuits 1642a, 1642b, . . . , 1642h corresponding to the plurality of operational amplifiers 1641a, 1641b, . . . , 1641h. The output buffer circuit 1640 of the source driver 1600 of FIG. 16 has a configuration of a buffer circuit according to the embodiments. The plurality of operational amplifiers 1641a, 1641b, . . . , 1641h may amplify the analog signals AD1, AD2, . . . , ADn from the DAC 1630 to generate data signals S1, S2, . . . , Sn. The plurality of slew rate compensating circuits 1642a, 1642b, . . . , 1642h may generate a compensation current based on a voltage difference of the analog signals AD1, AD2, . . . , ADn and the data signals S1, S2, . . . , Sn and may supply the compensation current to each of the plurality of operational amplifiers 1641 a, 1641b, . . . , 1641h. The compensation current may be proportional to the voltage difference of the analog signals AD1, AD2, . . . , ADn and the data signals S1, S2, . . . , Sn. Specifically, when the voltage difference of the analog signals AD1, AD2, . . . , ADn and the data signals S1, S2, . . . , Sn may be generated, the plurality of slew rate compensating circuits 1642a, 1642b, . . . , 1642h may generate a compensation current. The transition time of the output voltage may be reduced so that the source driver 1600 which includes the output buffer circuit 1640 may be driven at a low power and may be also driven at a high display frame rate.

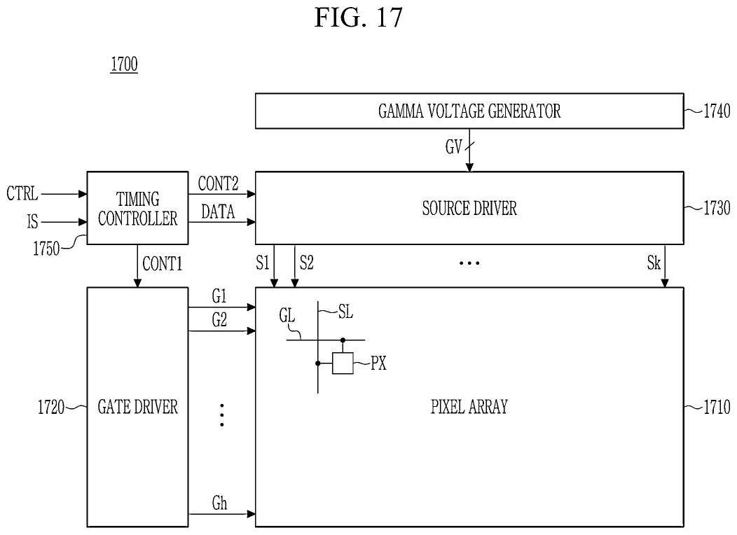

FIG. 17 is a block diagram illustrating a display device including a source driver according to an embodiment.

Referring to FIG. 17, a display device 1700 according to an embodiment may include a pixel array 1710, a gate driver 1720, a source driver 1730, a gamma voltage generator 1740, and a timing controller 1750.

A plurality of pixels PX for displaying images may be located in the pixel array 1710. The pixel PX may be connected to a corresponding source line SL among a plurality of source lines and a corresponding gate line GL among a plurality of gate lines. The pixel PX may receive a data signal from the source line SL when the gate signal may be supplied to the gate line GL. The pixel PX expresses light with a predetermined luminance corresponding to the input data signal. The plurality of pixel PX displays an image in one frame unit.

When the display device 1700 is an organic light emitting display device, each pixel PX may include a plurality of transistors including a driving transistor and an organic light-emitting diode. The driving transistor included in the pixel PX may supply a current corresponding to the data signal to the organic light-emitting diode and the organic light-emitting diode correspondingly emits light with a predetermined luminance. When the display device 1700 is a liquid crystal display device, each pixel PX may include a switching transistor and a liquid crystal capacitor. The pixel PX controls a transmittance of the liquid crystal in response to the data signal to supply the light with a predetermined luminance to the outside.

Even though in FIG. 17, it is illustrated that the pixel PX may be connected to one source line SL and one gate line GL, a connection structure of the signal line of the pixel PX of the display device according to the embodiment is not limited thereto. For example, various signal lines may be further connected in response to the circuit structure of the pixel PX. In the embodiment, the pixel PX may be implemented in various currently known forms.

The gate driver 1720 may supply a plurality of gate signals G1, G2, . . . , Gh. The plurality of gate signals G1, G2, . . . , Gh may be pulse signals having an enable level and a disable level. The plurality of gate signals G1, G2, . . . , Gh may be applied to the plurality of gate lines GL. When a gate signal of the enable level is applied to the gate line GL connected to the pixel PX, a data signal applied to the source line SL connected to the pixel PX may be transmitted to the pixel PX. The gate driver 1720 may supply the plurality of gate signal G1, G2, . . . , Gh during a plurality of horizontal periods. One frame may include a plurality of horizontal periods.

The source driver 1730 may receive a digital signal type of data DATA from the timing controller 1750 and converts the data DATA into an analog signal type of data signals S1, S2, . . . , Sk. Here, the data DATA may include gray information corresponding to each pixel PX to display the image signal may be on the pixel array 1710. The source driver 1730 transmits the plurality of data signals S1, S2, . . . , Sk to the pixel array 1710 according to the source driver control signal CONT3 supplied from the timing controller 1750. The source driver 1730 may be referred to as a data driver. In some embodiment, the source driver control signal CONT3 may include at least one of enable signals EN1, EN2, and EN and switching control signals SCS, SCS1, and SCS2 which have been described above.

The source driver 1730 may be electrically connected to the plurality of source lines SL. The source driver 1730 transmits the plurality of data signals S1, S2, . . . , Sk to the plurality of electrically connected source lines SL. The source driver 1730 may have the same configuration as the source driver 1600 of FIG. 16. Accordingly, the display device 1700 may include an output buffer circuit of the embodiment. The source driver 1730 may include a plurality of operational amplifiers which amplifies the input voltage and outputs the output voltage and a plurality of slew rate compensating circuits which generates a compensation current based on the difference between the input voltage and the output voltage. The transition time of the output voltage may be reduced so that the display device 1700 including the source driver 1730 may be driven at a low power and also may be driven at a high display frame rate.

The gamma voltage generator 1740 determines a magnitude of each of a plurality of gamma voltages GV based on an operating condition or gamma voltage register setting of the display device 1700. In the embodiment, the number of plurality of gamma voltages GV may be determined according to a number of bits of the image data. When the image data may have n bits, the plurality of gamma voltages GV may have 2n different magnitudes. The gamma voltage generator 1740 selects at least some of the plurality of reference voltages to determine a magnitude of each of the plurality of gamma voltages GV.

The timing controller 1750 may receive an image signal may be and a driving control signal CTRL from the host device and controls the gate driver 1720 and the source driver 1730. Here, the host device may be a computing device or system which controls the display device 1700 to display an image desired by a user on the pixel array 1710 from the outside. The driving control signal CTRL provided from the host device may include a control instruction and predetermined data to control the gate driver 1720 and the source driver 1730. The timing controller 1750 controls the gate driver 1720 and the source driver 1730 based on the driving control signal CTRL. For example, the driving control signal CTRL may include a horizontal synchronizing signal HSYNC, a vertical synchronization signal VSYNC, a main clock signal MCLK, and a data enable signal DE. The timing controller 1750 divides the image signal may be in one frame unit based on the vertical synchronization signal VSYNC and divides the image signal may be in a gate line (GL) unit based on the horizontal synchronizing signal HSYNC to generate data DATA. The timing controller 1750 may transmit the gate driver control signal CONT3 and the source driver control signal CONT3 to the gate driver 1720 and the source driver 1730, respectively, to control the synchronization of the operations of the source driver 1730 and the gate driver 1720, for example.

The pixel array 1710 and the gate driver 1720 may be implemented on the same substrate and the source driver 1730 and the timing controller 1750 are configured in one chip. In some embodiment, the pixel array 1710, the gate driver 1720, the source driver 1730, and the timing controller 1750 may be implemented on the same substrate. In some embodiment, the gate driver 1720, the source driver 1730, and the timing controller 1750 may be configured as one chip. The gate driver 1720 may be implemented as a separate semiconductor die, chip, or module to be connected to the pixel array 1710. Further, a part of the gate driver 1720 may be located on the substrate on which the pixel array 1710 may be located and the other part may be included in a separate chip.

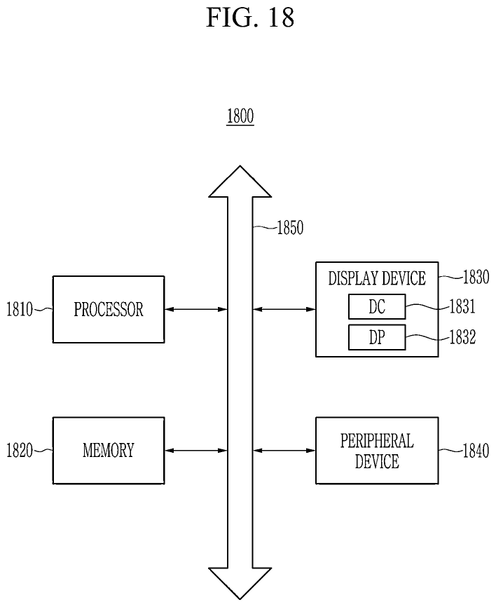

FIG. 18 is a view for explaining a display system according to an embodiment.

Referring to FIG. 18, a display system 1800 according to an embodiment may include a processor 1810, a memory 1820, a display device 1830, and a peripheral device 1840 which are electrically connected to a system bus 1850.

The processor 1810 controls the data input/output of the memory 1820, the display device 1830, and the peripheral device 1840 and may perform the image processing of the image data which are transmitted between the corresponding devices.

The memory 1820 may include a volatile memory such as a dynamic random access memory (DRAM) and/or a non-volatile memory such as a flash memory. The memory 1820 may be configured by a DRAM, a phase-change random access memory (PRAM), a magnetic random access memory (MRAM), a resistive random access memory (ReRAM), a ferroelectric random access memory (FRAM), a NOR flash memory, a NAND flash memory, and a fusion flash memory (for example, a memory in which a static random access memory (SRAM) buffer and a NAND flash memory and a NOR interface logic are coupled). The memory 1820 may store image data acquired from the peripheral device 1840 or stores image signal processed in the processor 1810.

The display device 1830 may include a driving circuit 1831 and a display panel 1832 and the driving circuit 1831 displays image data applied through the system bus 1850 on the display panel 1832. The driving circuit 1831 may include a source driver 1600 of FIG. 16. Specifically, the driving circuit 1831 may include a plurality of operational amplifiers which amplifies an input voltage and outputs an output voltage and a plurality of slew rate compensating circuits which generates a compensation current based on a difference of the input voltage and the output voltage. The transition time of the output voltage may be reduced so that the display device 1830 including the driving circuit 1831 may be driven at a low power and may be also driven at a high display frame rate.

The peripheral device 1840 may be a device which converts a moving image or a still image into an electric signal, such as a camera, a scanner, or a web cam. The image data acquired through the peripheral device 1840 may be stored in the memory 1820 and may be displayed on the panel 1831 in real time.

The display system 1800 may be equipped in a mobile electronic product, such as a smart phone, but may be not limited thereto and may be equipped in various types of electronic products which display images.

In some embodiment, each component which has been described with reference to FIGS. 1 to 18 and a combination of two or more components is implemented as a digital circuit, a programmable or non-programmable logic device, or an array, or an application specific integrated circuit (ASIC).

The foregoing exemplary embodiments are merely exemplary and are not to be construed as limiting. The present teaching can be readily applied to other types of apparatuses. Also, the description of the exemplary embodiments is intended to be illustrative, and not to limit the scope of the claims, and many alternatives, modifications, and variations will be apparent to those skilled in the art.

What is claimed is:

1. A buffer circuit comprising:
an operational amplifier configured to output an output voltage based on a voltage of a first output node and a voltage of a second output node which vary in response to an input voltage of the operational amplifier; and
a slew rate compensating circuit configured to receive the input voltage and the output voltage, generate a compensation current which is proportional to a voltage difference between the input voltage and the output voltage, and supply the compensation current to the first output node or the second output node.

2. The buffer circuit of claim 1, wherein the slew rate compensation circuit is further configured to provide the compensation current, based on the voltage difference occurring between the input voltage and the output voltage.

3. The buffer circuit of claim 1, wherein the operational amplifier is further configured to drop the output voltage based on the voltage of the first output node and raise the output voltage based on the voltage of the second output node, and
based on the input voltage being greater than the output voltage, the slew rate compensating circuit is further configured to supply the compensation current to the first output node to suppress a decrease of the output voltage, and based on the input voltage being less than the output voltage, supply the compensation current to the second output node to suppress an increase of the output voltage.

4. The buffer circuit of claim 3, wherein the compensation current which is supplied to the first output node comprises a first compensation current that sinks the current of the first output node to suppress the decrease of the output voltage, and
wherein the compensation current which is supplied to the second output node comprises a second compensation current provided to the second output node to suppress the increase of the output voltage.

5. The buffer circuit of claim 1, wherein the slew rate compensating circuit comprises:
a current generator configured to receive the input voltage and the output voltage and generate a current proportional to the voltage difference between the input voltage and the output voltage, and
a compensation current generator configured to perform an operation of a current mirror and generate the compensation current.

6. The buffer circuit of claim 5, wherein the current generator comprises:
a first amplifier comprising a first input stage to which the input voltage is applied, a second input stage connected to a first node, and an output stage configured to output the input voltage,
a first resistor which is connected between an output node configured to output the output voltage and the first node,
a second amplifier which comprises a first input stage to which the input voltage is applied, a second input stage connected to a second node, and an output stage configured to output the input voltage, and
a second resistor which is connected between the output node and the second node.

7. The buffer circuit of claim 6, wherein based on the input voltage being greater than the output voltage, a current proportional to the voltage difference between the input voltage and the output voltage flows in the first resistor and
based on the input voltage being less than the output voltage, a current proportional to the voltage difference between the input voltage and the output voltage flows in the second resistor.

8. The buffer circuit of claim 7, wherein the operational amplifier is further configured to drop the output voltage based on the voltage of the first output node and raise the output voltage based on the voltage of the second output node, and
the compensation current generator is further configured to perform the operation of the current mirror for the current which flows in the first resistor, supply the compensation current to the first output node, perform the operation of the current mirror for the current which flows in the second resistor, and supply the compensation current to the second output node.

9. The buffer circuit of claim 6, wherein based on the input voltage being greater than the output voltage, the first amplifier is further configured to be enabled by a first enable signal, and
based on the input voltage being less than the output voltage, the second amplifier is further configured to be enabled by a second enable signal.

10. The buffer circuit of claim 5, wherein the current generator comprises:
an amplifier comprising a first input stage to which the input voltage is applied, a second input stage connected to a first node, and an output stage configured to output the input voltage,
a resistor connected between the first node and an output node configured to output the output voltage, and
a plurality of switches configured to supply a current flowing from the first node to the output node to the compensation current generator based on the input voltage being greater than the output voltage, and supply a current flowing from the output node to the first node to the compensation current generator based on the input voltage being less than the output voltage.

11. The buffer circuit of claim 10, wherein based on the input voltage being different from the output voltage, the amplifier is further configured to be enabled by an enable signal.

12. The buffer circuit of claim 1, wherein the operational amplifier comprises:
an input stage configured to receive the input voltage and the output voltage and determine a magnitude difference between the input voltage and the output voltage,
a load stage configured to generate load currents corresponding to the magnitude difference between the input voltage and the output voltage and supply the load currents from the first output node and the second output node to the input stage, and
an output stage configured to generate the output voltage based on voltages of the first output node and the second output node.

13. The buffer circuit of claim 12, wherein the input stage of the operational amplifier further comprises:
a first input stage and a second input stage,
an upper bias circuit configured to supply a first bias current to the first input stage, and
a lower bias circuit configured to supply a second bias current to the second input stage.

14. The buffer circuit of claim 12, wherein the input stage comprises:
a first input stage comprising P-type transistors and configured to receive a pulling load current from the load stage, and
a second input stage comprising N-type transistors and configured to receive a pushing load current from the load stage.

15. The buffer circuit of claim 14, wherein the load stage comprises:
an upper current mirror circuit electrically connected to the second input stage and configured to supply a current to the load stage,
a lower current mirror circuit electrically connected to the first input stage and may supply a current to the load stage,
a first connection circuit configured to electrically connect a first output terminal of the upper current mirror circuit and a first output terminal of the lower current mirror circuit,
a second connection circuit configured to electrically connect a second output terminal of the upper current mirror circuit and a second output terminal of the lower current mirror circuit,
a first capacitor connected between the first output terminal of the upper current mirror circuit and an output terminal of the output stage, and
a second capacitor connected between the first output terminal of the lower current mirror circuit and the output terminal of the output stage.

16. A source driver, comprising:
a shift register configured to sample image data in response to a horizontal synchronizing signal and output sampled image data,
a level shifter configured to shift a voltage level of the image data,
a digital-analog converter (DAC) configured to generate an analog signal corresponding to the image data having the shifted voltage level, and
an output buffer circuit configured to buffer the analog signal to output the analog signal to source lines as a data signal, and generate a compensation current which is proportional to a voltage difference of the analog signal and the data signal.

17. The source driver of claim 16, wherein the output buffer circuit comprises:
a plurality of operational amplifiers configured to amplify the analog signal to generate the data signal, and
a plurality of slew rate compensating circuits configured to supply the compensation current to the plurality of operational amplifiers.

18. The source driver of claim 17, wherein the slew rate compensating circuit is further configured to supply the compensation current based on the voltage difference occurring between the analog signal and the data signal.

19. The source driver of claim 17, wherein the slew rate compensating circuit comprises:
a current generator configured to receive the analog signal and the data signal and generate the compensation current proportional to the voltage difference between the analog signal and the data signal, and
a compensation current generator configured to perform an operation of a current mirror for the current and generate the compensation current.

20. A display device, comprising:
a pixel array comprising a plurality of pixels,
a timing controller configured to obtain image data from an image signal, and
a source driver configured to convert the image data into a data signal and generate a compensation current proportional to a voltage difference between the image signal and the data signal based on the image data.

21. A buffer circuit comprising:
an operational amplifier comprising an input node configured to receive an input voltage and an output node configured to receive an output voltage; and
a slew rate compensating circuit comprising:
a first resistor provided and a second resistor connected in series with a common junction node between the first resistor provided and the second resistor, wherein the first resistor and the second resistor comprise a first opposite end node and a second opposite end node which are provided opposite to the common junction node, respectively;
a first mirror circuit connected to the first opposite end node and configured to mirror a rising compensation current flowing through the first resistor based on a difference between the input voltage and the output voltage; and
a second mirror circuit connected to the second opposite end node and configured to mirror a falling compensation current flowing through the second resistor based on a difference between the input voltage and the output voltage.
